(19) United States
(12) Patent Application Publication
(10) Pub. No.: US 2006/0283389 A1
(43) Pub. Date: Dec. 21, 2006

(54) System for growing silicon carbide crystals

(76) Inventors: GianLuca Valente, Milano (IT); Vittorio Pozzetti, Milano (IT); Olle Kordina, Butler, PA (US); Maurizio Masi, Milano (IT); Natale Speciale, Mazara del Vallo (IT); Danilo Crippa, Novara (IT); Franco Preti, Milano (IT)

Correspondence Address: KATTEN MUCHIN ROSENMAN LLP, 575 MADISON AVENUE, NEW YORK, NY, 10022-2585, US

(21) Appl. No.: 11/116,145

(22) Filed: Apr. 27, 2005

Related U.S. Application Data
(63) Continuation of application No. PCT/EP04/06244, filed on Jun. 9, 2004.

(30) Foreign Application Priority Data
Jun. 13, 2003 (IT) MI2003A001196

(51) Int. Cl. C23C 16/00

(52) U.S. Cl. 118/715

(57) ABSTRACT

A system for growing silicon carbide crystals on substrates is described and comprises a chamber (1) which extends along an axis, wherein the chamber (1) has separate input means (2, ;) for gases containing carbon and for gases containing silicon, substrate support means (4) disposed in a first end zone (ZI) of the chambe, exhaust output means (5) disposed in the vicinity of the support means (4), and heating means adapted for beating the chamber (1) to a temperature greater than 1800° C.′; the input means (2) for gases containing silicon are positioned, shaped and dimensioned in a manner such that the gases containing silicon enter in a second end zone (Z2) of the chamber; the input means (3) for gases containing carbon are positioned shaped and dimensioned in a manner such that the carbon and tire silicon come substantially into contact in a central zone (ZC) of the chamber remote both from the first end zone (ZI) and from the second end zone (Z2).

The present invention relates to a system for growing silicon carbide crystals according to the preamble to claim 1.

Various proposals have been put forward in the past for the growth, at very high temperatures (above 1800° C.), of silicon carbide crystals of a quality suitable for use in the microelectronics industry.

A first and basic proposal was put forward by Nisshin Steel in 1992; this is described in European patent EP554047. Nisshin Steel's concept provides for reaction gases containing silicon and carbon to be mixed together, for the gas mixture to be admitted to a reaction chamber at high-temperature, and for the mixed silicon and carbon to be deposited on a substrate, growing a crystal. Nisshin Steel's example of implementation provides for a preliminary chamber at intermediate temperature in which solid silicon carbide particles form.

This concept was taken up again in 1995 by OKMETIC; OKMETIC's solution is described in international patent application WO97/01658.

A second and basic proposal was put forward by Jury Makarov in 1999; this is described in international patent application WO00/43577. Makarov's concept provides for reaction gases containing silicon and carbon to be admitted separately to a reaction chamber at high-temperature and to be put in contact in the vicinity of a substrate so that the silicon and the carbon are deposited directly on the substrate, growing a crystal; Makarov's invention proposed that deposits of silicon carbide along the walls of the chamber be prevented, and therefore provided for silicon carbide to be caused to form solely in the vicinity of the substrate, that is, of the growing crystal. In investigating the solution proposed by Makarov, it has been realized that that solution is critical both from the chemical kinetics and from the flow-dynamics points of view.

The object of the present invention is to provide a third and basic proposal which is different from the previous ones and improved in comparison therewith.

This object is achieved by the system for growing silicon carbon crystals having the characteristics set forth in independent claim 1.

The concept underlying the present invention is to cause reaction gases containing carbon and gases containing silicon to enter a chamber by means of separate input means and to cause those gases to come into contact in a central zone of the chamber remote from the growth substrate.

The concentration profile and the velocity profile are thus substantially constant radially (clearly, there are inevitable edge effects); a constant growth rate, a uniform crystalline structure, and a uniform chemical composition are thus achieved throughout the cross-section of the substrate.

Advantageous aspects of the present invention are set forth in the dependent claims.

The present invention will become clearer from the following description which is to be considered in conjunction with the appended drawings, in which:

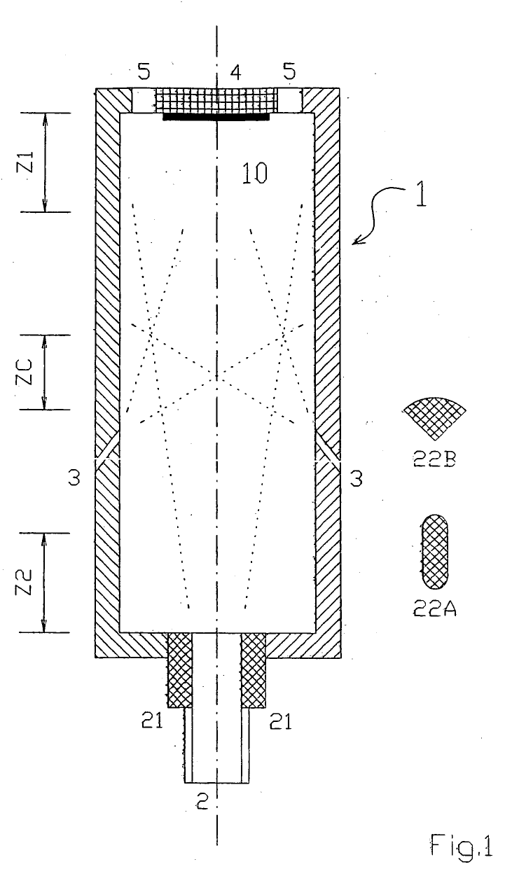

FIG. 1 is a schematic, sectioned view which assists in understanding the description of the teachings of the present invention,

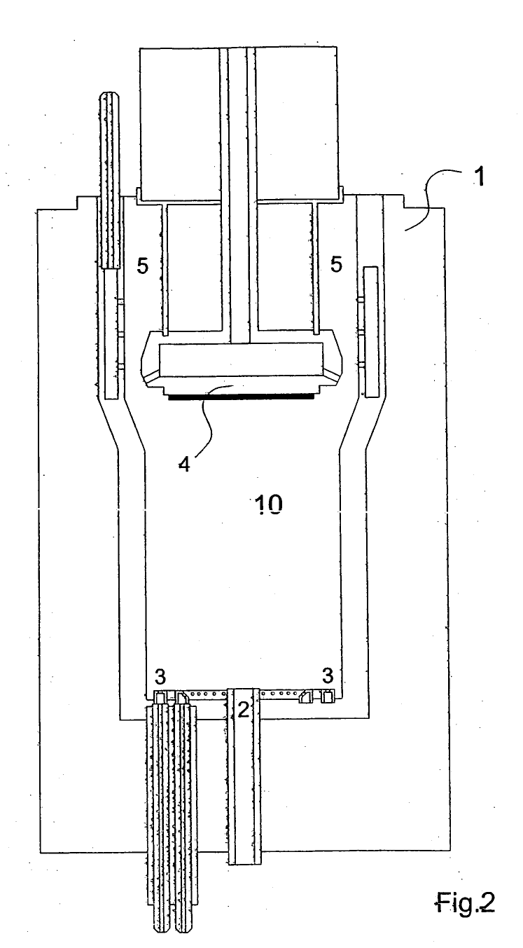

FIG. 2 shows a first embodiment of the present invention in a simplified, sectioned view, and

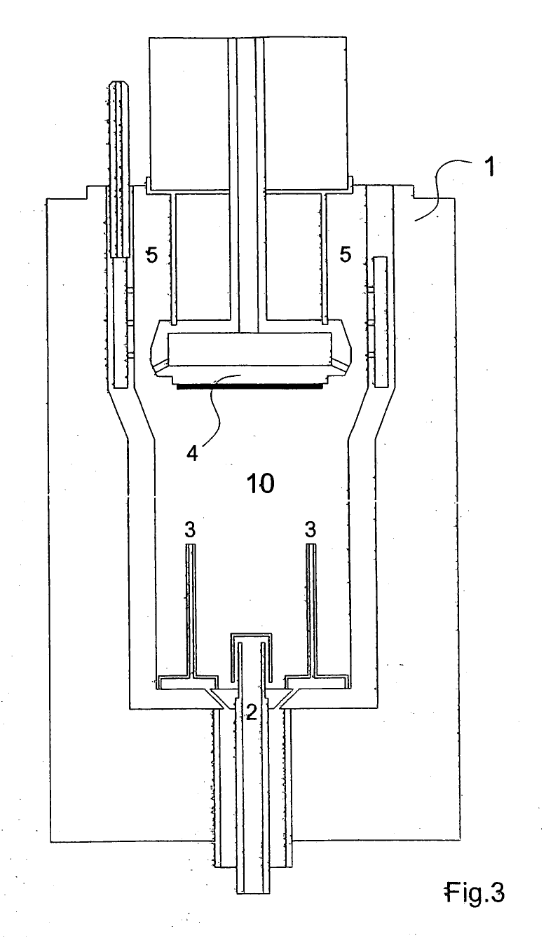

FIG. 3 shows a second embodiment of the present invention, in a simplified, sectioned view.

The system for growing silicon carbide crystals on substrates according to the present invention comprises a chamber which extends along an axis; typically, the axis is vertical; the chamber has:
separate input means for gases containing carbon and for gases containing silicon,
substrate support means disposed in a first end zone of the chamber,
exhaust output means disposed in the vicinity of the support means,
heating means adapted for heating the chamber to a temperature greater than 1800° C.;
   the input means for gases containing silicon are positioned, shaped and dimensioned in a manner such that the gases containing silicon enter in a second end zone of the chamber,
   the input means for the gases containing carbon are positioned, shaped and dimensioned in a manner such that the carbon and the silicon come substantially into contact in a central zone of the chamber remote both from the first end zone and from the second end zone.

In FIG. 1, the chamber is indicated 1, the space enclosed by the chamber is indicated 10, the input means for gases containing silicon are indicated 2, the input means for gases containing carbon are indicated 3, the substrate support means are indicated 4 (a substrate is shown fitted on the means 4 and indicated by a black line), the exhaust output means are indicated 5, an evaporation cell of the means 2 (which will be mentioned and described below) is indicated 21, two possible embodiments of central cores of the means 2 (which will be mentioned and described below) are indicated 22A and 22B, a level indicative of the first end zone of the chamber is indicated Z1, a level indicative of the second end zone of the chamber is indicated Z2, and a level indicative of the central zone of the chamber is indicated ZC. Moreover, in FIG. 1, an indicative distribution of the gases entering the chamber from the means 2 and 3 is shown by dotted lines and the axis of symmetry of the chamber is shown in chain line (however, the chamber of the system according to the invention is not necessarily symmetrical with respect to an axis).

The concentration profile and the velocity profile through the system specified above are substantially constant radially, at least in the first end zone of the chamber (clearly, there are inevitable edge effects); a constant growth rate, a uniform crystalline structure, and a uniform chemical composition are thus achieved over the entire cross-section of the substrate disposed on the support means.

Moreover, since the input zone for the gases containing silicon is remote from the zone of mixing with the gases containing carbon (the central zone ZC), and since the chamber is at a very high temperature, any liquid silicon particles that are formed at the input to the chamber or upstream of the input to the chamber evaporate and there is therefore no, risk of the formation of solid silicon carbide particles owing to contact of the carbon with the liquid particles; such solid silicon carbide particles are difficult to break up by sublimation (particularly if they are large) and, are very dangerous since they irremediably spoil the growing crystal if they strike its surface.

Finally, since the input zone for the gases containing silicon is remote from the zone of mixing with the gases containing carbon (the central zone ZC), it is possible to arrange for the concentration profile and the velocity profile of the gases containing silicon, upon their meeting, to be substantially constant radially (clearly, there are inevitable edge effects). According to the present invention, three zones are identified in the chamber: a first end zone (Z1), a central zone (ZC), and a second end zone (Z2). In all of the examples illustrated in the drawings (in particular in FIG. 1), the chamber has a substantially cylindrical shape and extends mainly substantially vertically (the most advantageous selection); the first end zone Z1 corresponds to the upper zone of the cylinder and the second end zone Z2 corresponds to the lower zone of the cylinder.

If low gas-flows are used in a system according to the present invention (as is preferable), the vertical orientation of the chamber causes any liquid silicon particles (particularly if they are large) to tend to remain at the bottom until they evaporate. By way of example, if the inside diameter of the chamber is 150 mm, the second end zone may extend from the base up to a height of about 50 mm, the central zone may extend from a height of about 100 mm to a height of about 150 mm, and the first end zone may extend from a height of about 200 mm to a height of about 250 mm. With appropriate selections of the various gas output means and of the flow-rates and velocities of the gas-flows, the lengths of the various zones and the distances between the various zones can be reduced considerably to less than half. Clearly, since the compounds containing silicon and the compounds containing carbon enter the chamber in gaseous form and since there is a very large degree of lateral diffusion because of the high temperature, it is not possible to define very precisely the zone in which they come into contact and the degree of mixing.

The exhaust output means may serve to discharge everything: reaction products, compounds and elements which have not reacted and/or have not been deposited, carrier gases, etching gases and, possibly (!), solid particles detached from the walls of the chamber and/or from the growing crystal.

The temperature of about 1800° C. corresponds approximately to the temperature limit of normal CVD processes for the growth of silicon carbide; moreover, this temperature of about 1800° C. constitutes a boundary temperature: typically, below 1800° C. there is 3C-type nucleation of the SiC and typically above 1800° C. there is 6H-type or 4H-type nucleation of the SiC; finally, this temperature of about 1800° C. ensures that the silicon is in the gaseous phase in the range of pressures (0.1-1.0 atmosphere) and dilutions (1%-20%) that are of interest.

If the input means for the gases containing carbon are positioned, shaped and dimensioned in a manner such that the carbon and the silicon come substantially into contact in a zone which is also remote from the chamber walls (as is, in part, the case in FIG. 1), the deposits of silicon carbide along the internal walls of the chamber are much more limited.

The chamber of the system according to the present invention may advantageously have input means for anti-nucleation gas; these may be positioned, shaped and dimensioned in many different ways, possibly combined with one another; hydrochloric acid [HCl] may advantageously be used as anti-nucleation gas; this compound reacts with the silicon in the gaseous phase, preventing nucleation phenomena; hydrochloric acid may advantageously be used in combination with hydrogen.

The chamber of the system according to the present invention may advantageously have input means for etching gas; these may be positioned, shaped and dimensioned in many different ways, possibly combined with one another; hydrochloric acid [HCl] may advantageously be used as etching gas; this compound attacks the solid deposits and the solid silicon and silicon carbide particles (in particular if they are polycrystalline); hydrochloric acid may advantageously be used in combination with hydrogen.

Input means for etching gas may be positioned, shaped and dimensioned so as to admit gas in the first end zone of the chamber (as in the embodiments of FIG. 2 and FIG. 3), that is, in the vicinity of the support means and of the exhaust output means. These means may serve to prevent the exhaust output means from being obstructed because of deposits of material. In the embodiments of FIG. 2 and FIG. 3, these means comprise a hollow sleeve (which also acts as a wall of the chamber in the upper zone of the chamber) which is in communication with a suitable duct and has a plurality of holes facing towards the interior of the chamber.

Input means for anti-nucleation gas may be positioned, shaped and dimensioned in a manner such as to admit gas in the second end zone of the chamber (as in the embodiment of FIG. 2), that is, in the vicinity of the input means for gases containing silicon. These means may serve to reduce the presence of liquid silicon particles in the chamber, in particular in the second zone of the chamber. In the embodiment of FIG. 2, these means comprise a plurality of nozzles arranged in a ring and oriented at an angle of about 45° towards the centre of the chamber.

Input means for anti-nucleation gas may be positioned, shaped and dimensioned in a manner such as to admit gas into the central zone of the chamber. These means may serve to reduce the presence of liquid silicon particles in the chamber, in particular in the central zone of the chamber.

Input means for etching gas may be positioned, shaped, and dimensioned in a manner such as to create a gas-flow substantially only along the walls of the chamber. These means may serve to remove and/or prevent deposits of silicon carbide along the walls of the chamber; in providing such a flow of etching gas along the walls, however, it is necessary to take account of its effect on the walls of the chamber which must be adequately protected.

The input means for etching gas may be adapted for causing a etching gas, typically hydrochloric acid, associated with a carrier gas, typically hydrogen, (alternatively, argon, helium, or a mixture of two or more of those gases) to enter the chamber; the proportions between etching gas and carrier gas may be, for example, 10 slm for hydrogen and 1-2 slm for hydrochloric acid.

The support means of the system according to the present invention may also advantageously have input means for etching gas (as in the embodiment of FIG. 2 and FIG. 3); these may be positioned, shaped and dimensioned in a manner such as to admit gas around the substrates. These means may serve to remove deposits of silicon carbide (particularly polycrystalline silicon carbide) in the region of the periphery of the support means and to limit the lateral growth of the crystal. In this case, the support means may be constituted, for example, by a thick disc provided with an internal cavity and mounted on a tube which is in communication with the cavity (as in the embodiments of FIG. 2 and FIG. 3); the tube is thermally insulated and chemically isolated; the etching gas is injected into the tube, flows through the cavity, and emerges from a plurality of holes formed in the periphery of the disc.

The system according to the present invention may advantageously comprise means for rotating the support means during the growth process (as in the embodiments of FIG. 2 and FIG. 3). An improved uniformity of the growth conditions in the region of the crystal surface is thus obtained.

The system according to the present invention may advantageously comprise means for retracting the support means during the growth process (as in the embodiments of FIG. 2 and FIG. 3). During growth, the crystal surface is thus substantially always in the same position in the chamber, irrespective of the length of the crystal that has grown and it is therefore easier to control the growth conditions in the region of the crystal surface.

The means for moving the support means may advantageously be protected both from the heat and from the chemical environment of the reaction chamber (as in the embodiments of FIG. 2 and FIG. 3).

In all of the embodiments shown in the drawings, the support means can support a single substrate, which is the simplest situation.

According to the present invention, the input means for gases containing silicon may be positioned, shaped and dimensioned in many different ways.

The simplest way of producing these means is by means of a duct which opens into the second zone of the chamber; if the chamber is vertical and cylindrical, the duct will typically be vertical and central. This duct is in communication with the chamber of the system and the temperature of the end portion of the duct will therefore be quite high, although lower than that of the chamber.

The mouth of the duct in the chamber may advantageously be formed with a flow-dynamic distributor adapted for rendering the velocity profiles uniform and preventing lateral vortices.

To limit the entry of liquid silicon particles into the chamber, this duct may advantageously have a silicon evaporation cell in the region of an end portion of the duct; such a cell is shown schematically and indicated 21 in FIG. 1; the most typical and the simplest way of evaporating the liquid silicon particles is by heating; in fact FIG. 1 shows schematically a graphite sleeve covered with a suitable material which can be heated by induction and by radiation.

In order to heat the gases containing silicon, the duct may advantageously have a central core in the region of an end portion of the duct; the central core may be heated by radiation from the walls of the duct; the core may be of various shapes and sizes; particular shapes and/or sizes may be designed to maximize heat exchanges between the duct walls and the core and between the core and the gas.

In order to improve the distribution of the gases containing silicon in the chamber, the duct may advantageously have a central core in the region of an end portion of the duct; the core may be of various shapes and sizes; particular shapes and/or sizes may be designed to prevent vortices and to control possible condensation along the walls.

If the central core is suitably shaped and dimensioned, it can thus serve both to heat and to distribute the gas.

FIG. 1 shows, by way of indication, only two examples of such cores (to be precise, this drawing shows them in section and not yet mounted in the end portion of the duct); the first core, indicated 22A, has a cylindrical shape with two hemispherical ends and can be inserted completely in the end portion of the duct; the second core, indicated 22B, has an inverted conical shape with a spherical cap in the base region and can be disposed above the outlet of the duct so that the tip of the cone is inserted in the duct but without blocking it.

To limit the entry of liquid silicon particles into the chamber, the input means for gases containing silicon may advantageously comprise a cup-shaped element having an opening facing towards the duct (as in the embodiment of FIG. 3). The cup is thus heated by radiation from the chamber walls and the gas which flows through the cup is heated quickly to high temperature by the walls of the cup; rapid heating is very advantageous since the time during which the silicon is at a temperature below the silicon dew point, and hence the growth time for silicon particles, (and therefore their size) are thus reduced; moreover, any particles (in particular liquid silicon particles) tend to be retained in the cup until they evaporate. Improved results are obtained if the duct extends into the cup (as in the embodiment of FIG. 3); the abrupt changes provided in the path which leads from the duct to the chamber thus in fact tend to eliminate the liquid silicon particles by impact.

Although FIG. 3 shows a cylindrical cup, the cup may be suitably shaped and dimensioned both with regard to the outer surface and with regard to the inner surface; particular shapes and/or sizes may be designed to prevent vortices, to maximize heat exchanges between the chamber walls and the cup and between the cup and the gas, and to control possible condensation along the walls.

According to the present invention, the input means for gases containing carbon may be positioned, shaped and dimensioned in many different ways.

The input means for gases containing carbon may comprise a plurality of nozzles arranged in a ring and opening into the second zone of the chamber (as in the embodiment of FIG. 2 in which the nozzles are facing substantially upwards); for a vertical, cylindrical chamber, the ring and the chamber are typically coaxial and the ring is typically positioned on the base of the cylinder (as in the embodiment of FIG. 2) or on the lower portion of the cylindrical wall. The nozzles should be shaped and dimensioned in a manner such that the jet of gas containing carbon is substantially in contact with the silicon in a central zone of the chamber; the shape of a nozzle determines the direction and the shape of the gas jet.

The input means for gases containing carbon may comprise a plurality of ducts which are arranged in a ring and which open into the central zone of the chamber (as in the embodiment of FIG. 3); for a vertical, cylindrical chamber, the ring and the chamber are typically coaxial and the ducts are typically all identical and parallel; for a good result, the mean diameter of the ring may be selected so as to be approximately equal to ⅔ of the inside diameter of the chamber. In the embodiment of FIG. 3, these ducts are in communication with a hollow disc adjacent the base of the chamber; a series of small ducts opens in the cavity of the disc; the small ducts extend as branches from a large coaxial duct.

The input means for gases containing carbon may comprise a ring-shaped duct which opens in the central zone of the chamber; for a vertical, cylindrical chamber, the ring and the chamber are typically coaxial; to permit a good distribution of the gases containing silicon (which enter in the second zone of the chamber), the mean diameter of the ring is advantageously only slightly less than the inside diameter of the chamber; in this case, a ring-shaped duct for etching gas may be provided in addition, positioned around the ring-shaped duct for gases containing carbon and close to the walls of the chamber so as to keep the chamber walls clear of silicon carbide deposits.

The input means for gases containing carbon should be designed so as to try to achieve good mixing with the gases containing silicon and a wide and uniform distribution of the gases in the chamber and to try to prevent vortices; it is also advantageous to take account of the possible diffusion of the gases containing carbon back towards the input for the gases containing silicon. Both with regard to the input means for the gases containing silicon and with regard to the input means for the gases containing carbon, the objective is to bring carbon and silicon to the region of the substrate and not onto the walls of the chamber.

The input means for precursor gases (containing silicon or carbon) are typically adapted for admitting to the chamber a precursor gas associated with, and hence diluted in, a carrier gas which may be hydrogen, argon, helium, or a mixture of two or more of those gases; the proportions between precursor gas and carrier gas may be, for example, 10 slm for the carrier gas and 1-2 slm for the precursor gas.

The most typical precursor gas carrying silicon is silane [SiH₄]; it may be advantageous to mix the silane [SiH₄] with hydrochloric acid [HCl] so as to prevent (or at least limit) the formation of silicon droplets anywhere in the ducts; alternatively, compounds containing both silicon and chlorine, such as dichlorosilane ([DCS], trichlorosilane [TCS] and silicon tetrachloride [SiCl₄] may be used.

The precursor gases carrying carbon may be propane [C₃H₈], ethylene [C₂H₄], or acetylene [C₂H₂]; of these, the compound which is most stable at high temperature is acetylene, the easiest to handle is propane, and the compromise compound is ethylene.

Since very high temperatures have to be maintained in the chamber, the heating means are advantageously of the induction type and are adapted for heating the chamber walls; the heating means are not shown in any of the drawings.

It is preferable to maintain a predetermined temperature profile; in particular, the temperature of the central zone of the chamber is advantageously very high (2200° C.-2600° C.), whereas the temperature of the first zone (and hence of the substrate and of the growing crystal) is a little lower (1800° C.-2200° C.) to promote condensation of the silicon carbide; the temperature of the first zone (the input zone for the gases containing silicon) should be very high (2200° C.-2600° C.) but may also be slightly lower (2000° C.-2400° C.) than the temperature of the central zone.

In a first embodiment, the heating means may therefore be adapted for producing the following temperatures in the chamber:
in the first zone, a temperature within the range of 1800-2200 degrees, preferably about 2000 degrees,
in the central zone, a temperature within the range of 2200-2600 degrees, preferably about 2400 degrees,
in the second zone, a temperature within the range of 2000-2400 degrees, preferably about 2200 degrees.

In a second embodiments the heating means may therefore be adapted for producing the following temperatures in the chamber:
in the first zone a temperature within the range of 1800-2200 degrees, preferably about 2000 degrees,
in the central zone, a temperature within the range of 2200-2600 degrees, preferably about 2400 degrees,
in the second zone, a temperature within the range of 2200-2600 degrees, preferably about 2400 degrees.

It is advantageous to arrange for the support means to comprise temperature control means. The support means of the system according to the present invention are typically made of graphite coated with a layer of SiC or TaC; these therefore also act as heating elements both by the induction effect and by the radiation effect. A gas-flow, for example, of hydrogen, may advantageously be used to control the temperature of the support means; a hydrogen flow of 25 slm absorbs a power of about 1 kW in order to be heated to 2000° C. from ambient temperature. In this case, the support means may be constituted, for example, by a thick disc provided with an internal cavity and mounted on a tube which is in communication with the cavity; the tube is thermally insulated and chemically isolated; the cooling gas is injected into the tube, flows through the cavity, and emerges from a plurality of holes formed in the periphery of the disc. In the embodiments of FIG. 2 and FIG. 3, the gas-flow inside the support means can advantageously be used both for etching and for temperature control.

Many of the component parts of the system according to the present invention may be made of graphite; typically, these parts should be covered by a protective layer, for example, of SiC and of TaC (which is more resistant).

In FIGS. 2 and 3, the same reference numerals as in FIG. 1 have been used to identify elements with identical or similar functions.

Although the drawings show only two specific embodiments of the present invention, it is clear from the foregoing description that the present invention may be implemented in very many different ways resulting from the combination of the many variants envisaged for its component means.

1. System for growing silicon carbide crystals on substrates, comprising a chamber which extends along an axis,
wherein the chamber has:
separate input means for gases containing carbon and for gases containing silicon,
substrate support means disposed in a first end zone of the chamber,—exhaust output means disposed in the vicinity of the support means,
heating means adapted for heating the chamber to a temperature greater than approximately 18000,
wherein
the input means for gases containing carbon are positioned, shaped and dimensioned in a manner such that the carbon and the silicon come substantially into contact in a central zone of the chamber remote both from the first end zone and from the second end zone
characterized in that
the input means for gases containing silicon comprise a duct which opens into the second end zone of the chamber and which has,
thereof, a silicon evaporation cell for evaporating liquid silicon particles.

2. System according to claim 1, in which the input means for gases containing carbon are positioned, shaped and dimensioned in a manner such that the carbon and the silicon come substantially into contact in a zone which is also remote from the walls of the chamber.

3. System according to claim 1, in which the chamber has input means for etching gas, which are positioned, shaped and dimensioned in a manner such as to admit gas in the first end zone of the chamber.

4. System according to claim 1, in which the chamber has input means for anti-nucleating gas, which are positioned, shaped and dimensioned in a manner such as to admit gas in the second end zone of the chamber.

5. System according to claim 1, in which the chamber has input means for anti-nucleation gas, which are positioned, shaped and dimensioned in a manner such as to admit gas in the central zone of the chamber.

6. System according to claim 1, in which the chamber has input means for etching gas, which are positioned shaped and dimensioned in a manner such as to create a gas-flow substantially only along the walls of the chamber.

7. System according to claim 1, in which the support means have input means for etching gas, which are positioned shaped and dimensioned in a manner such as to admit gas around the substrates.

8. System according to claim 1, comprising means for rotating the support means during the growth process.

9. System according to claim 1, comprising means for retracting the support means during the growth process.

10. System according to claim 1, in which the duct has, in the region of an end portion thereof, a central core for heating the gases containing silicon and/or distributing them in the chamber.

11. System according to claim 1, in which the input means for gases containing silicon comprise a cup-shaped element having an opening facing towards the duct.

12. System according to claim 11, in which the duct extends inside the cup.

13. System according to claim 1, in which the input means for gases containing carbon comprise a plurality of nozzles arranged in a ring and opening into the second zone of the chamber.

14. System according to claim 1, in which the input means for gases containing carbon comprise a plurality of ducts arranged in a ring and opening into the central zone of the chamber.

15. System according to claim 1, in which the input means for gases containing carbon comprise a ring-shaped duct opens in the central zone of the chamber.

16. System according to claim 1, in which the heating means are of the induction type and are adapted for heating the walls of the chamber.

17. System according to claim 1, in which the heating means are adapted for producing the following temperatures in the chamber:
the first zone, a temperature within the range of 1800-2200 degrees, preferably about 2000 degrees,
in the central zone a temperature within the range of 2200-2600 degrees preferably about 2400 degrees,
in the second zone, a temperature within the range of 2000-2400 degrees, preferably about 2200 degrees.

18. System according to claim 1, in which the heating means are adapted for producing the following temperatures in the chamber:
in the first zone a temperature within the range of 1800-2200 degrees, preferably about 200 degrees,
the central zone, a temperature within the range of 2200-2600 degrees, preferably about 2400 degrees,
in the second zone, a temperature within the range of 2200-2600 degrees, preferably about 2400 degrees.

19. System according to claim 1, in which the support means comprise temperature control means.
